(19) United States
(12) Patent Application Publication
(10) Pub. No.: US 2026/0173847 A1
(43) Pub. Date: Jun. 18, 2026

(54) INTEGRATED CIRCUIT INCLUDING HORIZONTALLY-EXTENDING MIDDLE-OF-LINE (MOL) STRUCTURE

(71) Applicant: SAMSUNG ELECTRONICS CO., LTD., Suwon-si (KR)

(72) Inventors: Jimin PARK, Suwon-si (KR); Taehyung KIM, Suwon-si (KR); Jungho DO, Suwon-si (KR); Jaehyun LIM, Suwon-si (KR)

(73) Assignee: SAMSUNG ELECTRONICS CO., LTD., Suwon-si (KR)

(21) Appl. No.: 19/421,783

(22) Filed: Dec. 16, 2025

(30) Foreign Application Priority Data
Dec. 17, 2024 (KR) 10-2024-0189072

(51) Int. Cl. H10W 20/42; H10B 10/00; H10D 62/13; H10W 20/41; H10W 20/43

(52) U.S. Cl. CPC H10W 20/422; H10B 10/12; H10D 62/151; H10W 20/427; H10W 20/43; H10W 20/435

(57) ABSTRACT

An integrated circuit including a horizontally-extending middle-of-line (MOL) structure is provided. The integrated circuit includes: a first wiring layer comprising a plurality of patterns each extending in a first horizontal direction; an active contact; and an active via connecting the active contact and at least two patterns among the plurality of patterns.

### CROSS-REFERENCE TO RELATED APPLICATION

This application is based on and claims priority under 35 U.S.C. § 119 to Korean Patent Application No. 10-2024-0189072, filed on Dec. 17, 2024, in the Korean Intellectual Property Office, the disclosure of which is incorporated by reference herein in its entirety.

### BACKGROUND

The disclosure relates to an integrated circuit, and more particularly, to an integrated circuit including a horizontally-extending middle-of-line (MOL) structure.

As semiconductor processes advance, the sizes of devices included in integrated circuits have been reduced, and the degree of integration of integrated circuits has increased. As semiconductor manufacturing processes are subdivided, research is being performed on an improved method of placing line patterns for supplying power or signals to semiconductor devices. For example, researches are directed to providing a sufficient space for line patterns in a semiconductor device is while enhancing voltage drop characteristics of the line patterns.

### SUMMARY

The disclosure provides an integrated circuit including a horizontally-extending middle-of-line (MOL) structure, for example, a bar-type pattern which is formed in an MOL layer.

The object of the disclosure is not limited to the aforesaid, but other objects not described herein will be clearly understood by those of ordinary skill in the art from descriptions below.

An integrated circuit according to one or more embodiments includes: a first wiring layer comprising a plurality of patterns each extending in a first horizontal direction; an active contact; and an active via connecting the active contact and at least two patterns among the plurality of patterns, and extending along the active contact.

An integrated circuit according to one or more embodiments includes: a wiring layer comprising a plurality of patterns each extending in a first horizontal direction; a first gate line and a second gate line each extending in a second horizontal direction intersecting the first horizontal direction; and a first gate contact connecting the first gate line and at least two patterns among the plurality of patterns or connecting the first gate line, the second gate line and a pattern among the plurality of patterns.

An integrated circuit according to one or more embodiments includes: a wiring layer comprising a plurality of patterns each extending in a first horizontal direction; an active contact; and a via connecting the active contact and the wiring layer, wherein the active via overlaps a first pattern and a second pattern among the plurality of patterns in a vertical direction.

### BRIEF DESCRIPTION OF DRAWINGS

Embodiments will be more clearly understood from the following detailed description taken in conjunction with the accompanying drawings in which:

FIG. 1 is a plan view for describing a layout of an integrated circuit according to one or more embodiments;

FIG. 2 is a cross-sectional view taken along line Y1-Y1′ of FIG. 1;

FIG. 3 is a plan view for describing a layout of an integrated circuit according to one or more embodiments;

FIG. 4 is a cross-sectional view taken along line Y2-Y2′ of FIG. 3;

FIG. 5 is a plan view for describing a layout of a standard cell included in an integrated circuit, according to one or more embodiments;

FIG. 6 is an enlarged perspective view of a region A of FIG. 5;

FIG. 7 is a cross-sectional view taken along line X1-X1′ of FIG. 5;

FIG. 8 is a plan view for describing a layout of a standard cell included in an integrated circuit, according to one or more embodiments;

FIG. 9 is a plan view for describing a layout of a standard cell included in an integrated circuit, according to one or more embodiments;

FIG. 10 is an enlarged perspective view of a region B of FIG. 9;

FIG. 11 is a block diagram of a memory device according to one or more embodiments;

FIG. 12 is a circuit diagram for describing a bit cell of an integrated circuit according to one or more embodiments;

FIG. 13 is a plan view for describing a layout of a portion of a control block of a memory device, according to one or more embodiments;

FIGS. 14A and 14B are plan views for describing a layout of a portion of a row driver of a memory device, according to one or more embodiments;

FIG. 15 is a block diagram illustrating a system-on-chip (SoC) according to one or more embodiments; and

FIG. 16 is a flowchart illustrating a method of manufacturing an integrated circuit, according to one or more embodiments.

### DETAILED DESCRIPTION

The embodiments described herein are non-limiting example embodiments, and thus, the disclosure is not limited thereto and may be realized in various other forms. Each of the embodiments provided herein is not excluded from being associated with one or more features of another example or another embodiment also provided herein or not provided herein but consistent with the disclosure. For example, even if matters described in a specific example or embodiment are not described in a different example or embodiment, the matters may be understood as being related to or combinable with the different example or embodiment, unless otherwise mentioned in descriptions thereof.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present

Hereinafter, various embodiments will be described with reference to the accompanying drawings. Herein, an X-axis direction and a Y-axis direction may be respectively referred to as a first horizontal direction and a second horizontal direction, and a Z-axis direction may be referred to as a vertical direction.

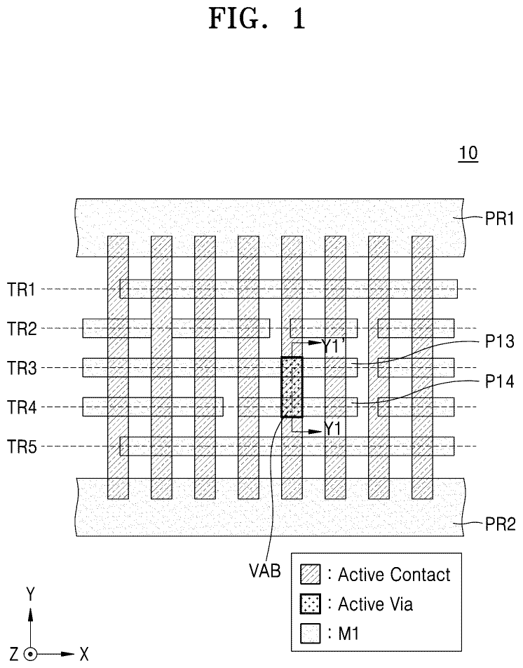

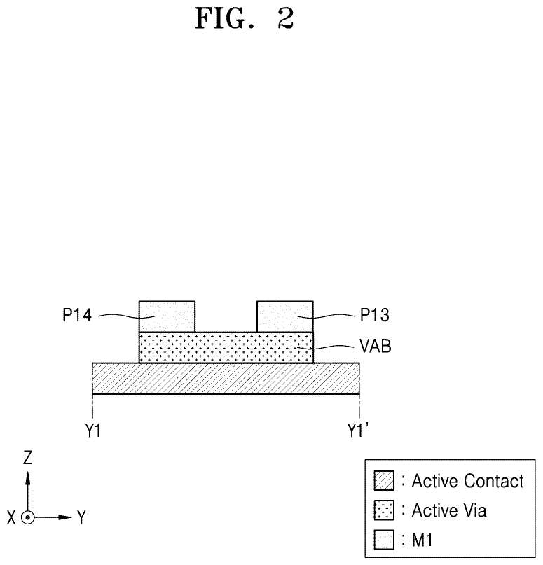

FIG. 1 is a plan view for describing a layout of an integrated circuit 10 according to one or more embodiments. FIG. 2 is a cross-sectional view taken along line Y1-Y1′ of FIG. 1.

Referring to FIG. 1, the integrated circuit 10 may include gate lines extending in a Y-axis direction on a substrate and may include active regions extending in an X-axis direction on the substrate. The active region and the gate line of the integrated circuit 10 may configure a transistor (for example, a field effect transistor (FET)).

The substrate may include a semiconductor material such as silicon (Si) or germanium (Ge) or a Group III-V compound such as GaAs, AlGaAs, InAs, InGaAs, InSb, GaSb, InGaSb, InP, GaP, InGaP, InN, GaN, or InGaN. In one or more embodiments, the substrate may be a silicon-on-insulator (SOI) substrate or a germanium-on-insulator (GOI) substrate.

A plurality of active contacts (also referred to as contact structures or contact plugs) may be formed in the active region formed in the substrate. The plurality of active contacts may be formed to extend in the Y-axis direction. In FIG. 1, it is illustrated that the plurality of active contacts extend by the same length, but this may be for describing an extension direction of the plurality of active contacts, and each of the plurality of active contacts may be formed by various lengths, based on the kind of semiconductor devices formed in the integrated circuit 10 and a connection relationship therebetween.

A plurality of wiring layers where wirings for connecting the semiconductor devices with each other are formed may be formed to be stacked in the integrated circuit 10. Patterns respectively formed in the plurality of wiring layers may include metal (e.g., metal lines, patterns, contacts, vias, etc.), conductive metal nitride, metal silicide, or a combination thereof. In the drawings, only some wiring layers may be illustrated for convenience of illustration, and a first wiring layer M1 illustrated in FIG. 1 may be a layer (i.e., the lowermost wiring layer) disposed closest to the substrate among the plurality of wiring layers.

In each of the plurality of wiring layers, a direction in which a pattern extends may be designated. In each of the plurality of wiring layers, a region where a pattern (e.g., a metal line) is formed may be defined as a track. For example, patterns extending in an X-axis direction may be formed in odd-numbered wiring layers from the substrate, and patterns extending in a Y-axis direction may be formed in even-numbered wiring layers from the substrate. Different wiring layers among the plurality of wiring layers may be connected to each other through a via passing through an insulation layer surrounding the patterns.

A plurality of tracks where patterns are disposed may be defined at least in the first wiring layer M1. The plurality of tracks of the first wiring layer M1 may extend in the X-axis direction and may be apart from each other in the Y-axis direction. For example, first to fifth tracks TR1 to TR5 of the first wiring layer M1 may be disposed between a first power rail PR1 and a second power rail PR2 of the integrated circuit 10. However, the disclosure is not limited thereto, and the number of tracks of the first wiring layer M1 disposed may be variously modified based on a distance (i.e., a cell height of a standard cell disposed) between the first power rail PR1 and the second power rail PR2.

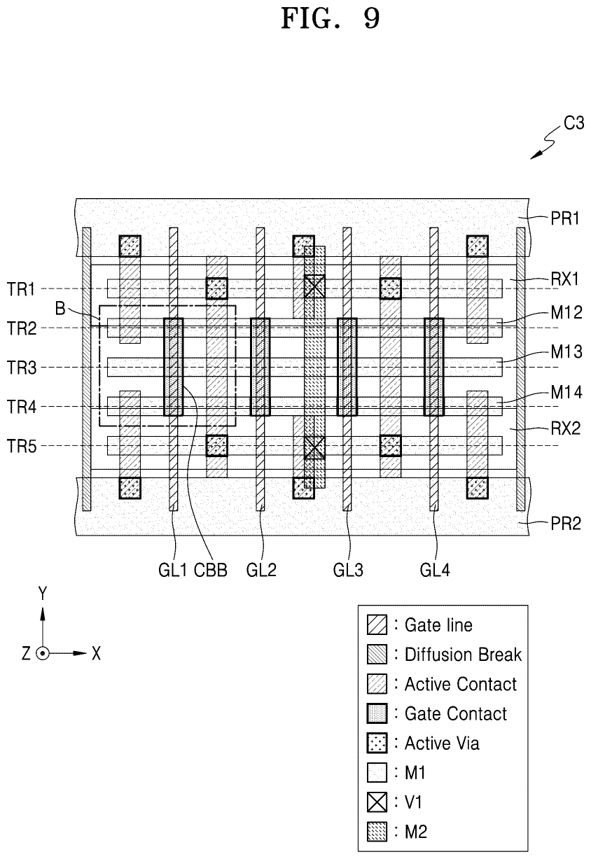

Also, a plurality of tracks where patterns are disposed may be defined in a second wiring layer (for example, M2 of FIG. 9) disposed on the first wiring layer M1. The second wiring layer M2 may be a wiring layer disposed on the first wiring layer M1 and may be the second lowermost wiring layer among the plurality of wiring layers. The plurality of tracks of the second wiring layer M2 may extend in the Y-axis direction and may be apart from each other in the X-axis direction. The first wiring layer M1 and the second wiring layer M2 may be connected to each other through at least one first via (for example, V1 of FIG. 9).

Referring to FIGS. 1 and 2, the integrated circuit 10 may include a bar-type active via VAB, which connects the first wiring layer M1 to an active contact selected from among the plurality of active contacts. The bar-type active via VAB may extend in the Y-axis direction along a contacting active contact and may be formed to contact at least two patterns successively disposed or arranged in the Y-axis direction in the first wiring layer M1.

In one or more embodiments, the bar-type active via VAB may be disposed on the active contact to contact a pattern P13 of a third track TR3 and a pattern P14 of a fourth track TR4. For example, the pattern P13 of the third track TR3 may be connected to an output pin of a first standard cell included in the integrated circuit 10, and the pattern P14 of the fourth track TR4 may be connected to an output pin of a second standard cell included in the integrated circuit 10. In this case, the first standard cell and the second standard cell may be standard cells disposed adjacent to each other, or a filler cell may be disposed between the first standard cell and the second standard cell.

In an integrated circuit of a comparative example where the bar-type active via VAB is not formed, patterns of the second wiring layer M2, which is an upper layer on the first wiring layer M1, and patterns of the third wiring layer M3, which is an upper layer on the second wiring layer M2, may be needed for electrically connecting the pattern P13 of the third track TR3 and the pattern P14 of the fourth track TR4 with each other, and a first via for connecting the first wiring layer M1 and the second wiring layer M2 with each other and a second via for connecting the second wiring layer M2 and the third wiring layer M3 with each other may be further needed. Therefore, the integrated circuit 10 according to one or more embodiments may transfer a signal through the bar-type active via VAB formed in a middle-of-line (MOL) layer, and thus, a routing space of a plurality of wiring layers, including the first wiring layer M1, the second wiring layer M2, and the third wiring layer M3, may be secured.

In FIGS. 1 and 2, only the bar-type active via VAB extending along the active contact is illustrated, but the integrated circuit 10 may further include a bar-type active via which extends in the X-axis direction along or on a pattern of the first wiring layer M1.

The integrated circuit 10 may include the first power rail PR1 and the second power rail PR2, which supply a voltage to a semiconductor device. The first power rail PR1 may supply a first supply voltage (for example, a source voltage VDD) to the semiconductor device, and the second power rail PR2 may supply a second supply voltage (for example, a ground voltage VSS) to the semiconductor device. In one or more embodiments, the first power rail PR1 and the second power rail PR2 may be formed by a conductive pattern extending in the X-axis direction of the first wiring layer M1 and may be alternately arranged in the Y-axis direction.

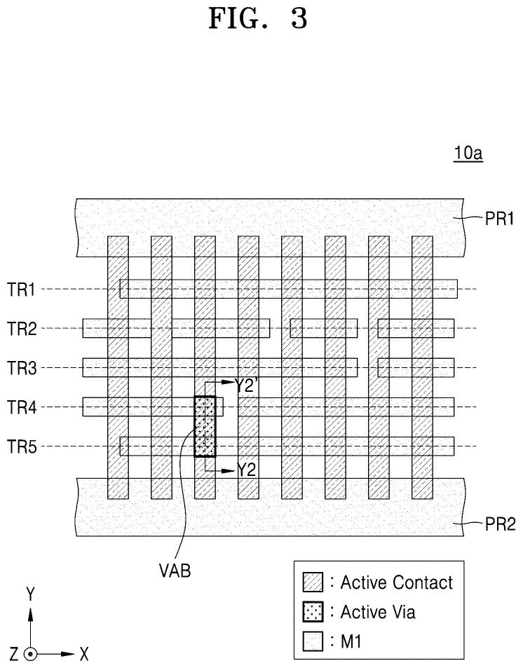

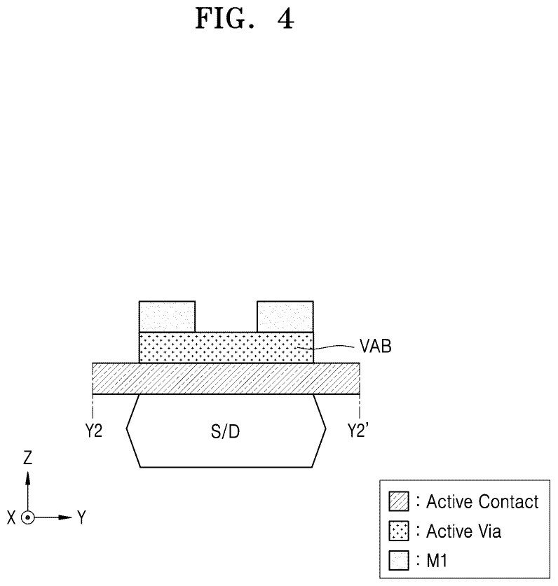

FIG. 3 is a plan view for describing a layout of an integrated circuit 10a according to one or more embodiments. FIG. 4 is a cross-sectional view taken along line Y2-Y2′ of FIG. 3. In describing FIGS. 3 and 4, repeated descriptions of the same reference numerals as FIGS. 1 and 2 may be omitted.

Referring to FIGS. 3 and 4, the integrated circuit 10a may include a bar-type active via VAB, which connects a first wiring layer M1 to an active contact selected from among a plurality of active contacts. The bar-type active via VAB may extend in a Y-axis direction along the active contact and may be formed to contact at least two patterns successively disposed or arranged in the Y-axis direction in the first wiring layer M1.

A source/drain region S/D may contact a lower portion of the bar-type via VAB. The source/drain region S/D may include an epitaxially-grown semiconductor layer. For example, the source/drain region S/D may include a semiconductor layer which is epitaxially grown from an active region. The source/drain region S/D may be formed in an embedded silicon germanium (SiGe) structure which includes an epitaxial grown silicon (Si) layer, an epitaxial grown silicon carbide (SiC) layer, and a plurality of epitaxial grown SiGe layers. A metal silicide layer may be formed of an upper surface of each source/drain region S/D on a bottom surface of the active contact thereon.

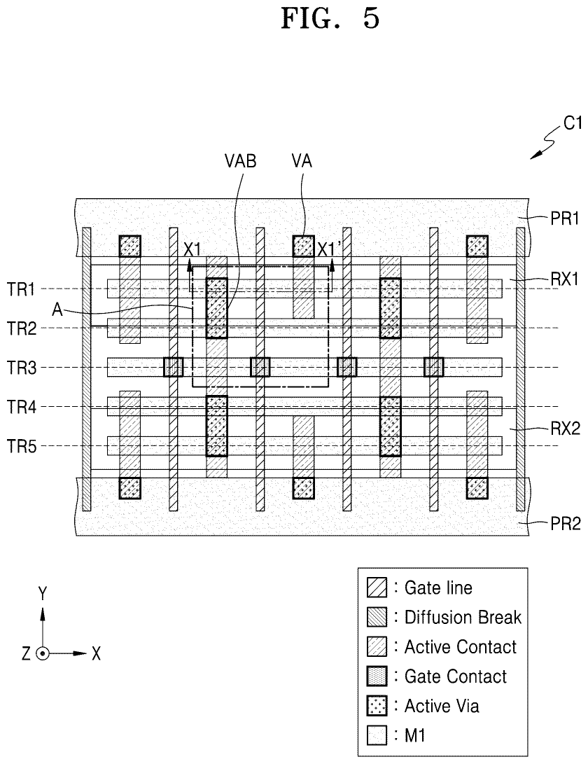

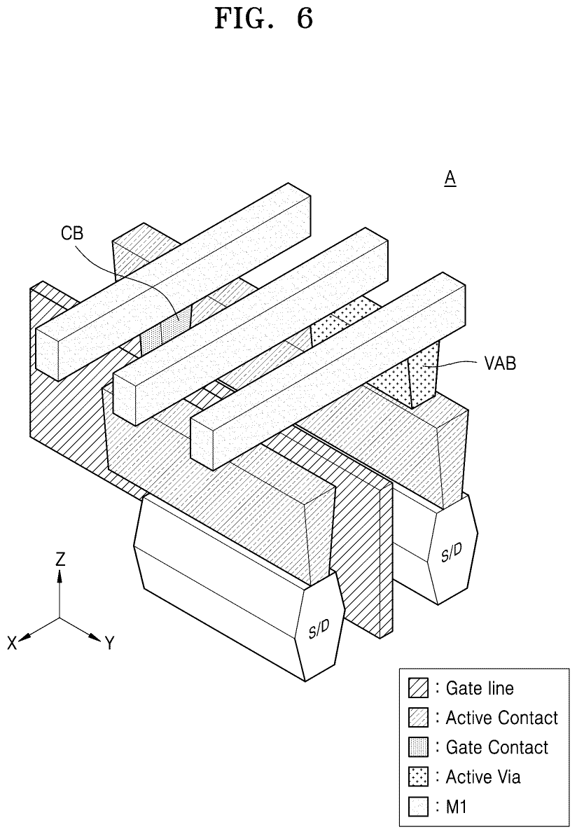

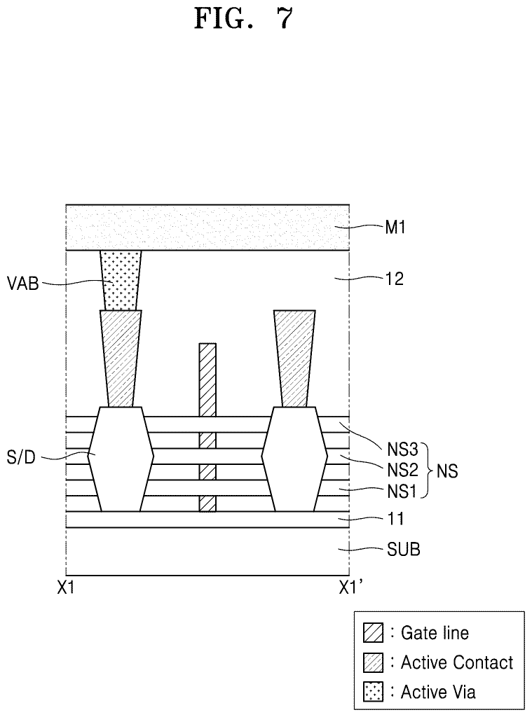

FIG. 5 is a plan view for describing a layout of a standard cell C1 included in an integrated circuit, according to one or more embodiments. FIG. 6 is an enlarged perspective view of a region A of FIG. 5. FIG. 7 is a cross-sectional view taken along line X1-X1′ of FIG. 5. In describing FIG. 5, repeated descriptions of the same reference numerals as FIGS. 1 and 2 may be omitted.

An integrated circuit configuring one chip or one function block may include a plurality of standard cells. The standard cell may be a unit of a layout included in the integrated circuit and may be defined by a cell boundary. The standard cell may be designed to perform a predefined function and may be referred to as a cell. The integrated circuit may include a plurality of various standard cells.

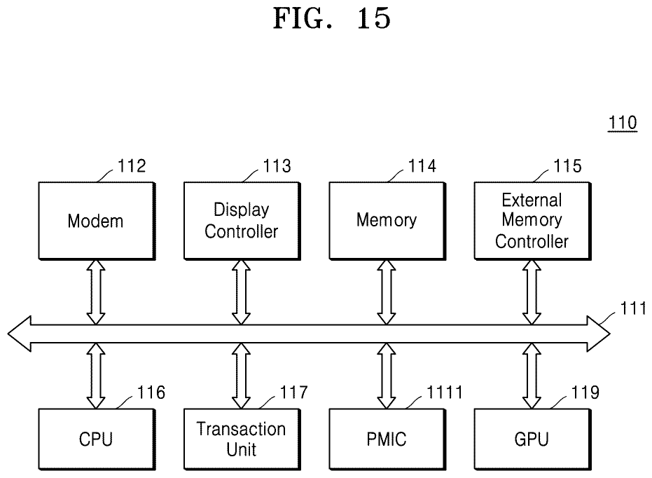

The plurality of standard cells may be repeatedly used in an integrated circuit design. The standard cells may be designed based on manufacturing technology and may be stored in a cell library (for example, D10 of FIG. 15), and the standard cells stored in a standard cell library D10 may be disposed based on a design rule and may be connected to each other, thereby designing an integrated circuit.

For example, the standard cells may include various basic circuits such as inverters, AND gates, NAND gates, OR gates, XOR gates, and NOR gates, not being limited thereto, which are frequently used in a digital circuit design for electronic devices such as designs of central processing unit (CPU), graphics processing unit (GPU), and system-on-chip (SoC), not being limited thereto. Alternatively or additionally, for example, the standard cells may include another circuit frequently used in a circuit block like a flip-flop and a latch.

Referring to FIGS. 5 and 6, the standard cell C1 may be a standard cell where an inverter is implemented and may be one or more embodiments of a standard cell included in an integrated circuit including a middle-of-line (MOL) pattern of a bar type. The standard cell C1 may be defined by a cell boundary, and a first power rail PR1, a second power rail PR2, and a diffusion break may be formed in the cell boundary. The diffusion break may electrically isolate the standard cell C1 from active regions of other standard cells. In FIG. 5, a single diffusion break replacing with one gate line is illustrated, but is not limited thereto and a double diffusion break may be formed in the cell boundary. The diffusion break may include a silicon-containing insulation layer, such as silicon oxide, silicon nitride, silicon oxynitride, or silicon carbide, or a combination thereof. For example, the diffusion break may include fluoride silicate glass (FSG), undoped silicate glass (USG), boro-phospho-silicate glass (BPSG), phospho-silicate glass (PSG), flowable oxide (FOX), plasma enhanced tetra-ethyl-ortho-silicate (PE-TEOS), or tonen silazene (TOSZ).

The standard cell C1 may include a first active region RX1 and a second active region RX2, which extend in an X-axis direction. In one or more embodiments, the second active region RX2 may be formed in a substrate SUB doped with P-type impurities, and the first active region RX1 may be formed in an N-well formed in the substrate SUB. The first active region RX1 may configure a gate line and a P-type transistor, and the second active region RX2 may configure a gate line and an N-type transistor.

A plurality of active contacts extending in a Y-axis direction may be formed on a source/drain region S/D formed in the first active region RX1 and the second active region RX2. A plurality of active vias may be disposed on the plurality of active contacts, and an active via may electrically connect an active contact to a first wiring layer M1. Therefore, the source/drain region S/D may be connected to the first wiring layer M1 through the active contact and the active via.

The active via may include a square-type active via VA and a bar-type active via VAB, which connect one active contact to one pattern of the first wiring layer M1. In this case, the bar-type active via VAB may connect one active contact to two or more patterns of the first wiring layer M1, or may connect two or more active contacts to one pattern of the first wiring layer M1.

For example, tracks where patterns for routing are formed may be defined in the first wiring layer M1, and the bar-type active via VAB may be connected to patterns disposed in two or more adjacent tracks of a plurality of tracks (for example, first to fifth tracks TR1 to TR5) of the first wiring layer M1. Therefore, in order to connect the standard cell C1 to another standard cell which receives an output signal output from the standard cell C1 to operate, routing connected to one of patterns of the first track TR1, the second track TR2, the fourth track TR4, and the fifth track TR5 of the standard cell C1 may be formed, and the degree of freedom of routing may increase. Also, a voltage drop characteristic of routing between the standard cell C1 and the other standard cell may be enhanced.

The standard cell C1 may include a plurality of gate lines extending in the Y-axis direction. In one or more embodiments, the gate line may include a work function metal-containing layer and a gap-fill metal layer. For example, the work function metal-containing layer may include at least one metal of titanium (Ti), tungsten (W), ruthenium (Ru), niobium (Nb), molybdenum (Mo), hafnium (Hf), nickel (Ni), cobalt (Co), platinum (Pt), ytterbium (Yb), terbium (Tb), dysprosium (Dy), erbium (Er), and palladium (Pd), and the gap-fill metal layer may include a W layer or an Al layer. In one or more embodiments, the gate line may include a stack structure of TiAlC/TiN/W, a stack structure of TiN/TaN/TiAlC/TiN/W, or a stack structure of TiN/TaN/TiN/TiAlC/TiN/W.

A gate contact may be disposed on at least one of the plurality of gate lines, and the gate contact may electrically connect the gate line to the first wiring layer M1. In FIG. 6, an example where a gate contact CB is formed to contact a gate line and a pattern of the first wiring layer M1 has been described, but the disclosure is not limited thereto and a gate via may be further formed between the gate contact and the first wiring layer M1. and thus, the gate line and the first wiring layer M1 may be connected to each other through the gate contact and the gate via.

Referring to FIGS. 5 and 7, a nanosheet stack NS may be formed in at least one of the first active region RX1 and the second active region RX2, and the nanosheet stack NS may extend in the Y-axis direction. A device insulation layer 11 may be formed between the substrate SUB and the nanosheet stack NS.

The nanosheet stack NS may function as a channel of a transistor. For example, the nanosheet stack NS disposed in the first active region RX1 of the substrate SUB may be doped with N-type impurities and may configure a P-type transistor. In one or more embodiments, the nanosheet stack NS may include Si, Ge, or SiGe. In one or more embodiments, the nanosheet stack NS may include InGaAs, InAs, GaSb, InSb, or a combination thereof.

A nanosheet stack NS may include a plurality of nanosheets NS1 to NS3 which overlap each other in the vertical direction (Z-axis direction). In one or more embodiments, a case where the nanosheet stack NS includes three nanosheets may be described, but the disclosure is not limited thereto. For example, the nanosheet stack NS may include at least two nanosheets, and the number of nanosheets is not limited thereto.

The gate line may surround each of the plurality of nanosheets NS1 to NS3 while covering the nanosheet stack NS. A multi bridge channel (MBC) FET where a gate line surrounds a plurality of nanosheets may be formed. A gate insulation layer may be disposed between the nanosheet stack NS and the gate line.

The standard cell C1 included in the integrated circuit according to one or more embodiments is not limited to the illustration of FIG. 7, and a Fin FET which includes one or more fins and a gate line formed in the first active region RX1 and the second active region RX2 may be formed, or for example, a gate-all-around (GAA) FET where a nanowire formed in at least one of the first active region RX1 and the second active region RX2 is surrounded by a gate line may be formed. A vertical GAA FET where a plurality of nanowires are vertically stacked and are surrounded by a gate line GL may be formed in at least one of the first active region RX1 and the second active region RX2. Also, for example, a negative capacitance (NC) FET may be formed in at least one of the first active region RX1 and the second active region RX2. In addition to the transistor described above, various different types of transistor (for example, a complementary FET (CFET), a negative complementary FET (NCFET), a carbon nanotube (CNT) FET, a bipolar junction transistor, and other three-dimensional (3D) transistors) may be formed in the standard cell C1.

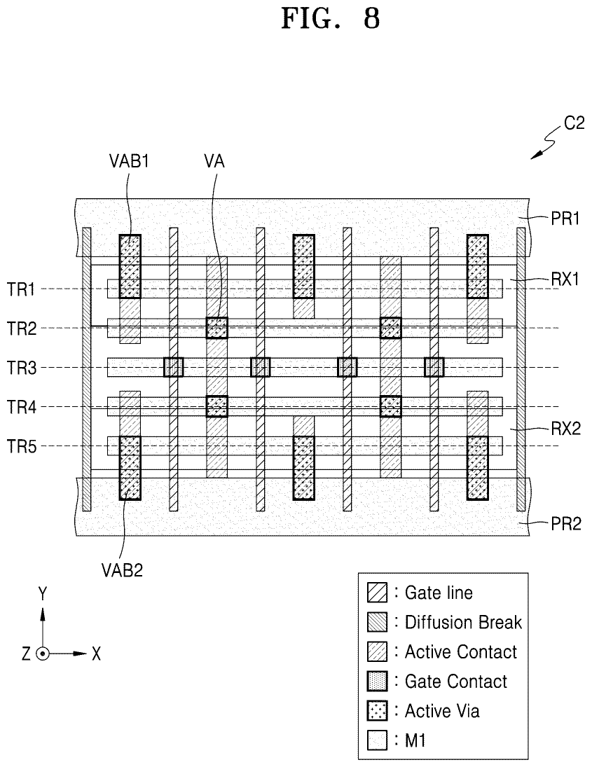

FIG. 8 is a plan view for describing a layout of a standard cell C2 included in an integrated circuit, according to one or more embodiments. In describing FIG. 8, repeated descriptions of the same reference numerals as FIG. 5 may be omitted.

Referring to FIG. 8, the standard cell C2 may be a standard cell where an inverter is implemented and may be one or more embodiments of a standard cell included in the integrated circuit according to one or more embodiments. In the standard cell C2, an active via may be disposed on a plurality of active contacts, and the active via may electrically connect an active contact to a first wiring layer M1.

The active via may include a square-type active via VA and a bar-type active via VAB1 or VAB2, which connect one active contact to one pattern of the first wiring layer M1. In this case, the bar-type active via VAB1 or VAB2 may connect one active contact to two or more patterns of the first wiring layer M1, or may connect two or more active contacts to one pattern of the first wiring layer M1.

At this time, the bar-type active via VAB1 or VAB2 may be formed to contact one of a first power rail PR1 and a second power rail PR2. For example, a first active via VAB1 may electrically connect the first power rail PR1 to a pattern of a first track TR1 of the first wiring layer M1, and a second active via VAB2 may electrically connect the second power rail PR2 to a pattern of a fifth track TR5 of the first wiring layer M1. Therefore, a voltage drop (IR drop) characteristic of a first supply voltage provided by the first power rail PR1 may be improved, and a voltage drop characteristic of a second supply voltage provided by the second power rail PR2 may be improved. The standard cell C2 of FIG. 8 may include all of the first active via VAB1 and the second active via VAB2, but is not limited thereto and may include at least one of the first active via VAB1 and the second active via VAB2.

In FIG. 8, bar-type active vias VAB1 and VAB2 connected to the first power rail PR1 and the second power rail PR2, respectively, are illustrated, but the disclosure is not limited thereto. The integrated circuit according to one or more embodiments may include the bar-type active vias VAB1 and VAB2 of FIG. 8 and may further include one or more bar-type active vias VAB connected to patterns of two or more tracks disposed adjacent to each other described above with reference to FIG. 5.

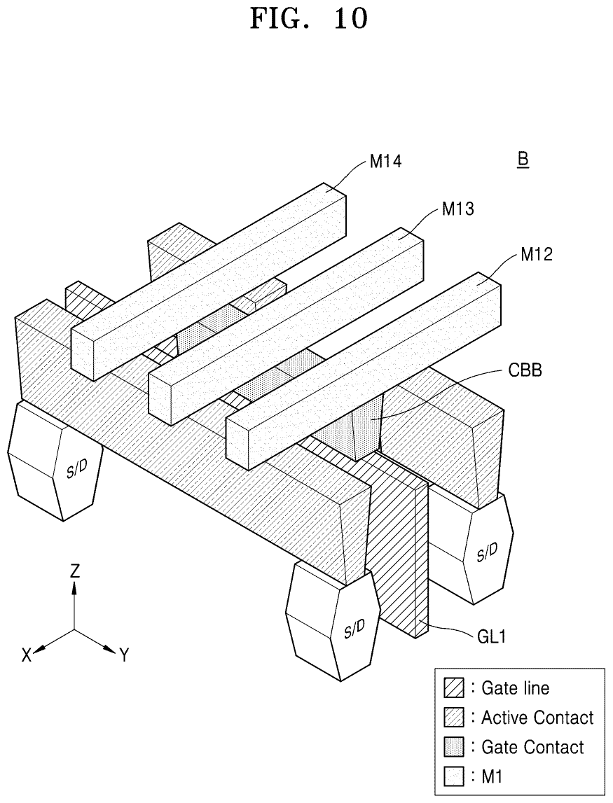

FIG. 9 is a plan view for describing a layout of a standard cell C3 included in an integrated circuit, according to one or more embodiments. FIG. 10 is an enlarged perspective view of a region B of FIG. 9. In describing FIG. 9, repeated descriptions of the same reference numerals as FIG. 5 may be omitted.

Referring to FIGS. 9 and 10, the standard cell C3 may be a standard cell where an inverter is implemented and may be one or more embodiments of a standard cell included in an integrated circuit including an MOL pattern of a bar type. The standard cell C3 may include a plurality of gate lines (for example, first to fourth gate lines) GL1 to GL4 extending in a Y-axis direction.

A gate contact may be disposed on each of the plurality of gate lines GL1 to GL4, and the gate contact may electrically connect the gate line to a first wiring layer M1. The standard cell C3 may include a bar-type gate contact CBB. In this case, the bar-type gate contact CBB may extend along a gate line in a Y-axis direction and may connect the gate line to two or more patterns of the first wiring layer M1, or may extend along a pattern of the first wiring layer M1 in an X-axis direction and may connect two or more gate lines to one pattern of the first wiring layer M1.

Tracks where patterns for routing are formed may be defined in the first wiring layer M1, and the bar-type gate contact CBB may be connected to patterns disposed in two or more adjacent tracks of a plurality of tracks (for example, first to fifth tracks TR1 to TR5) of the first wiring layer M1. For example, the bar-type gate contact CBB may be connected to patterns M12 to M14 of second to fourth tracks TR2 to TR4.

In one or more embodiments, the bar-type gate contact CBB may be disposed on each of the plurality of gate lines GL1 to GL4 included in the standard cell C3. In one or more embodiments, each of the plurality of gate lines GL1 to GL4 may be connected to the same patterns (for example, M12, M13, and M14) of the first wiring layer M1 through the bar-type gate contact CBB formed thereon. For example, the same input signal may be input to the plurality of gate lines GL1 to GL4 and may receive an input signal through the patterns M12 to M14 of the second to fourth tracks TR2 to TR4 identically connected thereto.

Therefore, in order to connect the standard cell C3 to another standard cell which outputs an input signal input to the standard cell C3, routing connected to one of the patterns M12 to M14 of the second to fourth tracks TR2 to TR4 of the standard cell C3 may be formed, and the degree of freedom of routing may increase. Also, a voltage drop characteristic of routing between the standard cell C3 and the other standard cell may be enhanced. In FIG. 9, it is illustrated that the bar-type gate contact CBB is formed on each of the first to fourth gate lines GL1 to GL4 which are all gate lines included in the standard cell C3, but the disclosure is not limited thereto and the bar-type gate contact CBB may be formed on only some of the plurality of gate lines GL1 to GL4 included in the standard cell C3.

In FIG. 9, only the bar-type gate contact CBB is illustrated, but is not limited thereto and the integrated circuit according to one or more embodiments may further include at least one of the bar-type active via VAB of FIG. 5 and the bar-type active via VAB1 or VAB2 of FIG. 8.

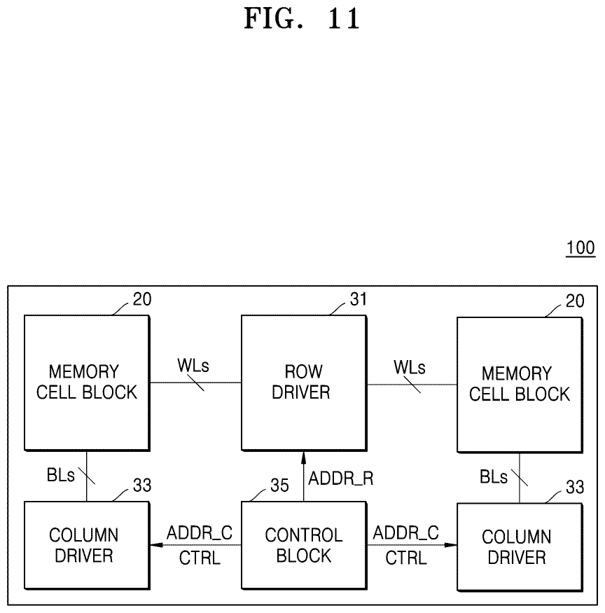

FIG. 11 is a block diagram of a memory device 100 according to one or more embodiments.

Referring to FIG. 11, an integrated circuit according to one or more embodiments may be the memory device 100. The memory device 100 may be static random access memory (RAM) (SRAM), dynamic RAM (DRAM), mobile DRAM, flash memory, electrically erasable programmable read-only memory (EEPROM), resistive RAM (PRAM), phase-change RAM (RRAM), or ferroelectric RAM (FRAM), but is not limited thereto. Hereinafter, for convenience of description, the memory device 100 will be described based on SRAM.

The memory device 100 may receive a command, an address, a clock signal, and data and may output data. For example, the memory device 100 may receive a command indicating write, an address, and data which is write data and may store the data in a region of a memory cell block 20 corresponding to the address. Also, the memory device 100 may receive an address and a command indicating read and may output read data, stored in a region of a memory cell block 20 corresponding to the address, as data to the outside of the memory device 100.

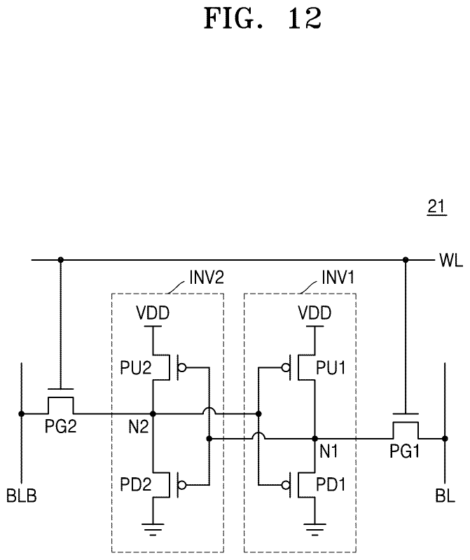

The memory device 100 may include the memory cell block 20 and a peripheral circuit. The memory cell block 20 may include a plurality of bit cells (for example, 21 of FIG. 12). The plurality of bit cells 21 may be arranged at a certain interval in a plurality of memory columns and a plurality of memory rows. The plurality of bit cells 21 may be disposed at points at which a plurality of word lines WLs intersect a plurality of bit lines BLs. That is, each of the plurality of bit cells 21 may be connected to at least one of the plurality of word lines WLs and may be connected to at least one of the plurality of bit lines BLs.

Each of the plurality of bit cells 21 may be a memory cell. For example, each of the plurality of bit cells 21 may be an SRAM cell, or for example, may be a volatile memory cell such as DRAM. In one or more embodiments, each of the plurality of bit cells 21 may be a non-volatile memory cell such as flash memory or resistive RAM (RRAM). In embodiments, an example where each of the plurality of bit cells 21 is an SRAM cell may be mainly described, but embodiments are not limited thereto.

The peripheral circuit may receive an address, a command, and a clock signal from the outside of the memory device 100 and may transfer or receive data to or from a device outside the memory device 100. The peripheral circuit may include a row driver 31, a column driver 33, and a control block 35. The peripheral circuit may write or read data in or from the memory cell block 20.

The row driver 31 may be connected to the memory cell block 20 through the plurality of word lines WLs. The row driver 31 may activate at least one of the plurality of word lines WLs, based on a row address ADDR_R. For example, the row driver 31 may select at least one word line WL from among the plurality of word lines WLs. Therefore, bit cells connected to an activated word line may be selected from among the plurality of bit cells 21.

The column driver 33 may be connected to the memory cell block 20 through the plurality of bit lines BLs. The column driver 33 may select at least one bit line from among the plurality of bit lines BLs, based on a column address ADDR_C. The bit line BL and a complementary bit line BLB may be connected to at least one of the plurality of bit cells 21, and thus, as the column driver 33 selects the bit line BL and the complementary bit line BLB, bit cells 21 connected to the bit line BL and the complementary bit line BLB may be selected.

The column driver 33 may perform a read operation or a write operation, based on a control signal CTRL. The column driver 33 may include a read driver which performs a read operation and a write driver which performs a write operation.

The read driver may sense a current and/or a voltage received through the plurality of bit lines BLs, and thus, may identify values stored in a bit cell connected to an activated word line among the plurality of bit cells 21 and may output data, based on the identified values. The write driver may apply the current and/or the voltage to the plurality of bit lines BLs, based on the data received from the outside of the memory device 100, and may write the values in the bit cell connected to the activated word line among the plurality of bit cells 21.

The control block 35 may receive a command, an address, and a clock signal to generate the row address ADDR_R, the column address ADDR_C, and the control signal CTRL. For example, the control block 35 may decode the command to identify a read command and may generate the row address ADDR_R, the column address ADDR_C, and the control signal CTRL so as to read data from the memory cell block 20. Also, the control block 35 may decode the command to identify a write command and may generate the row address ADDR_R, the column address ADDR_C, and the control signal CTRL so as to write data in the memory cell block 20.

In the memory device 100 which is one or more embodiments of the integrated circuit according to one or more embodiments, the control block 35 may provide the control signal CTRL and the column address ADDR_C to the column driver 33 and may provide the row address ADDR_R to the row driver 31, and thus, a number of signal lines for providing a signal output from the control block 35 may be needed. Accordingly, it may be required to secure a routing space in a plurality of wiring layers, for transferring the control signal CTRL, and improve a voltage drop characteristic.

In the memory device 100 according to one or more embodiments, in the peripheral circuit, for example, the row driver 31, the column driver 33, and the control block 35, the bar-type active via VAB of FIGS. 1, 3, and 5, the bar-type active via VAB1 or VAB2 of FIG. 8, or the bar-type gate contact of FIG. 9 may be provided, and thus, a routing space of a wiring layer may be secured, and a voltage drop characteristic of a signal input/output to/from a semiconductor device or a supply voltage provided to the semiconductor device may be improved.

FIG. 12 is a circuit diagram for describing a bit cell 21 of an integrated circuit according to one or more embodiments.

Referring to FIG. 21, the bit cell 21 may be an SRAM unit cell. The bit cell 21 may include a first inverter INV1, a second inverter INV2, a first pass element PG1, and a second pass element PG2.

The first inverter INV1 and the second inverter INV2 may output data having opposite phases. In detail, the first inverter INV1 may include a first pull-up element PU1 and a first pull-down element PD1. The first pull-up element PU1 may be a PMOS transistor, and the first pull-down element PD1 may be an NMOS transistor, but the disclosure is not limited thereto.

The second inverter INV2 may include a second pull-up element PU2 and a second pull-down element PD2. The second pull-up element PU2 may be a PMOS transistor, and the second pull-down element PD2 may be an NMOS transistor, but the disclosure is not limited thereto.

Sources of the first and second pull-down elements PD1 and PD2 may be connected to a first voltage (for example, a ground voltage), and sources of the first and second pull-up elements PU1 and PU2 may be connected to a second voltage (for example, a source voltage VDD) which is higher than the first voltage. A drain of the first pull-up element PU1 and a drain of the first pull-down element PD1 may be connected to a first node N1, and a drain of the second pull-up element PU2 and a drain of the second pull-down element PD2 may be connected to a second node N2. Also, an input of the first inverter INV1 may be connected to the second node N2 which is an output node of the second inverter INV2, and an input of the second inverter INV2 may be connected to the first node N1 which is an output node of the first inverter INV1.

A gate of the first pass element PG1 may be connected to a word line WL, a drain thereof may be connected to a bit line BL, and a source thereof may be connected to the first node N1. A gate of the second pass element PG2 may be connected to the word line WL, a drain thereof may be connected to a complementary bit line BLB, and a source thereof may be connected to the second node N2. Here, an inverted signal of a signal of the bit line BL may be applied to the complementary bit line BLB.

The bit cell 21 may operate as follows. When an electric potential of the word line WL is logic high, the first pass element PG1 and the second pass element PG2 may be turned on, and signals of the bit line BL and the complementary bit line BLB may be respectively transferred to the first inverter INV1 and the second inverter INV2, and thus, an operation of writing or reading data may be performed.

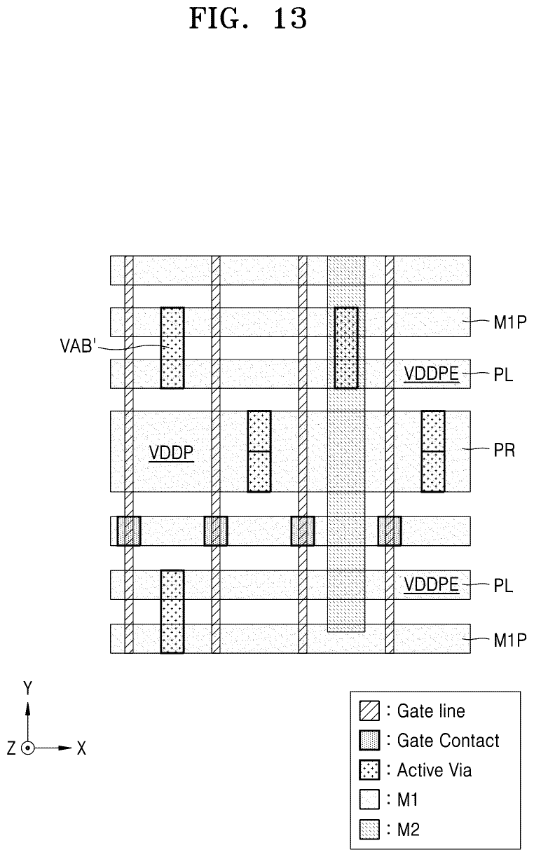

FIG. 13 is a plan view for describing a layout of a portion of a control block 35 of a memory device 100, according to one or more embodiments. In FIG. 13, the control block 35 may be described for example, and the descriptions of FIG. 13 may be similarly applied to other elements of a peripheral circuit of the memory device 100.

Referring to FIG. 13, the control block 35 of the memory device 100 may include a plurality of active regions which are formed to extend in an X-axis direction on a substrate and a plurality of gate lines which are formed to extend in a Y-axis direction. A plurality of active contacts may be formed to contact a source/drain region formed in the plurality of active regions, and an active via may be formed on each of the plurality of active contacts.

Also, a plurality of wiring layers where wirings for connecting semiconductor devices with each other are formed may be formed to be stacked in the control block 35 of the memory device 100. A first wiring layer M1 illustrated in FIG. 13 may be a layer (i.e., the lowermost layer) disposed closest to the substrate among the plurality of wiring layers.

A plurality of tracks where patterns are disposed may be defined in the first wiring layer M1, based on a design rule. The plurality of tracks of the first wiring layer M1 may extend in the X-axis direction and may be apart from each other in the Y-axis direction. Also, a plurality of tracks where patterns are disposed may be defined in a second wiring layer M2 disposed on the first wiring layer M1. The second wiring layer M2 may be a wiring layer disposed on the first wiring layer M1 and may be a wiring layer, disposed to be the second lowermost wiring layer among the plurality of wiring layers. The plurality of tracks of the second wiring layer M2 may extend in the Y-axis direction and may be apart from each other in the X-axis direction. The first wiring layer M1 and the second wiring layer M2 may be connected to each other through at least one first via.

A power rail PR which provides a supply voltage VDDP used in the control block 35 and a power line PL which provides an external supply voltage VDDPE provided from the outside to the control block 35 may be formed in the control block 35. For example, the power rail PR and the power line PL may be formed as a pattern of the first wiring layer M1.

Also, a bar-type active via VAB′ extending in the Y-axis direction may be formed in the control block 35. For example, the power line PL providing the external supply voltage VDDPE may be formed as a pattern of the first wiring layer M1, and the bar-type active via VAB′ may connect the power line PL to a pattern M1P of the first wiring layer M1 adjacent thereto. The pattern M1P of the first wiring layer M1 may additionally operate as the power line PL through the bar-type active via VAB′, and a voltage drop characteristic of the power line PL may be improved. In FIG. 13, only the bar-type active via VAB′ connected to the power line PL for transferring a voltage is illustrated, but the disclosure is not limited thereto. The control block 35, as described above in the standard cell C1 of FIG. 5, may be formed to connect, with each other, an active contact and a plurality of patterns formed in different tracks of the first wiring layer M1 for transferring a signal.

A gate contact for connecting a gate line to the first wiring layer M1 may be formed on each of a plurality of gate lines. In FIG. 13, only a square-type gate contact connecting one gate line to one pattern of the first wiring layer M1 is illustrated, but the disclosure is not limited thereto. As described above in the standard cell C3 of FIG. 9, the control block 35 may include a bar-type gate contact which connects one gate line to a plurality of patterns of the first wiring layer M1, and moreover, may include a bar-type gate contact which connects a plurality of gate lines to one pattern of the first wiring layer M1.

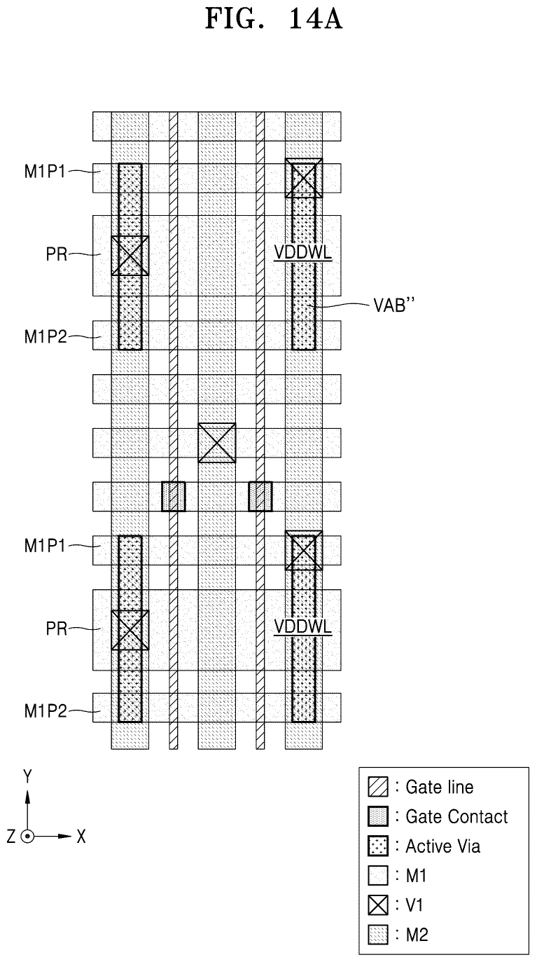

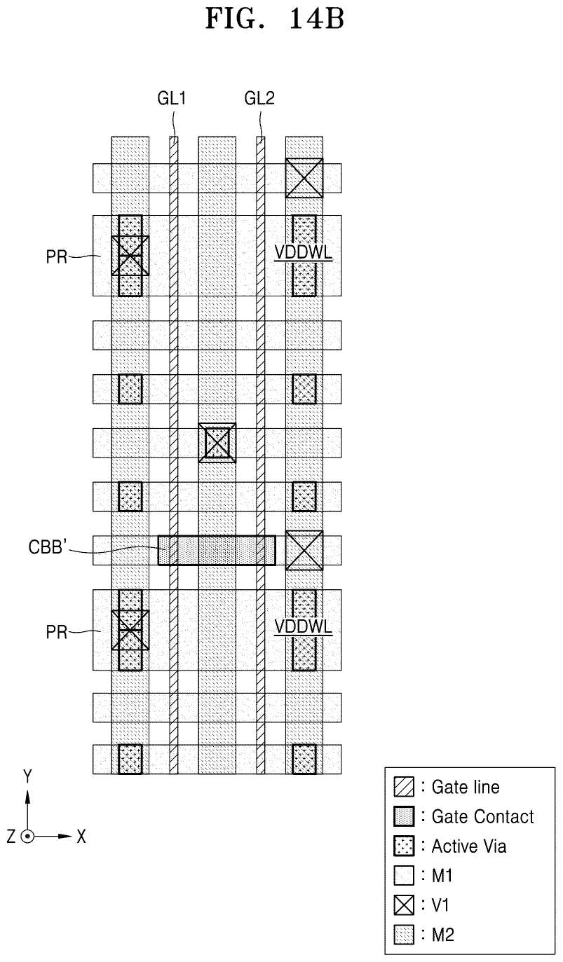

FIGS. 14A and 14B are plan views for describing a layout of a portion of a row driver 31 of a memory device 100, according to one or more embodiments. In FIGS. 14A and 14B, the row driver 31 may be described for example, and the descriptions of FIGS. 14A and 14B may be similarly applied to other elements of a peripheral circuit of the memory device 100.

Referring to FIG. 14A, the row driver 31 of the memory device 100 may include a plurality of active regions which are formed to extend in an X-axis direction on a substrate and a plurality of gate lines which are formed to extend in a Y-axis direction. A plurality of active contacts may be formed to contact source/drain regions formed in the plurality of active regions, and an active via may be formed on each of the plurality of active contacts.

Also, a plurality of wiring layers where wirings for connecting semiconductor devices with each other are formed may be formed to be stacked in the row driver 31 of the memory device 100. A first wiring layer M1 illustrated in FIG. 14A may be a layer (i.e., the lowermost layer) disposed closest to the substrate among the plurality of wiring layers.

Patterns extending in an X-axis direction may be formed in the first wiring layer M1, based on a design rule, or patterns extending in a Y-axis direction may be formed in a second wiring layer M2 disposed on the first wiring layer M1, based on the design rule. The first wiring layer M1 and the second wiring layer M2 may be connected to each other through at least one first via V1.

A power rail PR providing a supply voltage VDDWL used in the row driver 31 may be formed in the row driver 31. For example, the power rail PR may be formed as a pattern of the first wiring layer M1.

A bar-type active via VAB″ extending in the Y-axis direction may be formed in the row driver 31. For example, the power rail PR may be formed as the pattern of the first wiring layer M1, and the bar-type active via VAB″ may connect, with each other, patterns (for example, a first pattern M1P1 and a second pattern M1P2) of a plurality of first wiring layers M1 which are successively arranged in the Y-axis direction and include the power rail PR. Therefore, a width of the power rail PR may substantially increase, and thus, the bar-type active via VAB″ may be provided, thereby improving a voltage drop characteristic of the power rail PR.

In FIG. 14A, only the bar-type active via VAB″ connected to the power line PL for transferring a voltage is illustrated, but the disclosure is not limited thereto. The row driver 31, as described above in the standard cell C1 of FIG. 5, may be formed to connect, with each other, an active contact and a plurality of patterns formed in different tracks of the first wiring layer M1 for transferring a signal.

Referring to FIG. 14B, a bar-type gate contact CBB′ extending in the X-axis direction may be formed in the row driver 31. For example, the bar-type gate contact CBB′ may be formed to connect, with each other, a plurality of gate line GL1 and GL2 successively arranged in the X-axis direction. That is, the bar-type gate contact CBB′ may extend along a pattern of the first wiring layer M1. Accordingly, the plurality of gate line GL1 and GL2 may be connected to a pattern of one first wiring layer M1 through the bar-type gate contact CBB′, and thus, a voltage drop characteristic of the first wiring layer M1 connected to the plurality of gate line GL1 and GL2 may be improved.

In FIG. 14B, only the bar-type gate contact CBB′ which extends in the X-axis direction and connects the plurality of gate line GL1 and GL2 to one pattern of the first wiring layer M1 is illustrated, but the disclosure is not limited thereto. As described above in the standard cell C3 of FIG. 9, the row driver 31 may include a bar-type gate contact which connects one gate line to a plurality of patterns of the first wiring layer M1.

The bar-type active via VAB″ is illustrated in FIG. 14A, and the bar-type gate contact CBB′ is illustrated in FIG. 14B, but all of the bar-type active via VAB″ and the bar-type gate contact CBB′ may be formed in the peripheral circuit of the memory device 100 according to one or more embodiments.

FIG. 15 is a block diagram illustrating a system-on-chip (SoC) 110 according to one or more embodiments.

The SoC 110 may be a semiconductor device and may include at least one of the integrated circuits described above, according to one or more embodiments. In the SoC 110, complicated blocks such as intellectual property (IP) performing various functions may be implemented in one chip, and according to embodiments, the SoC 110 may efficiently provide various channel lengths and may have high efficiency and reliability.

Referring to FIG. 15, the SoC 110 may include a modem 112, a display controller 113, a memory 114, an external memory controller 115, a central processing unit (CPU) 116, a transaction unit 117, a power management integrated circuit (PMIC) 118, and a graphics processing unit (GPU) 119, and the function blocks of the SoC 110 may communicate with each other through a system bus 111.

The CPU 116 for controlling an operation of the SoC 110 in an uppermost layer may control operations of the other function blocks 112 to 119. The modem 112 may demodulate a signal received from the outside of the SoC 110, or may modulate a signal generated in the SoC 110 to transmit a modulated signal to the outside. The external memory controller 115 may control an operation of transmitting or receiving data to or from an external memory device connected to the SoC 110. For example, a program and/or data stored in the external memory device may be provided to the CPU 116 or the GPU 119, based on control by the external memory controller 115. The GPU 119 may execute program instructions associated with graphics processing. The GPU 119 may receive graphics data through the external memory controller 115, or may transmit graphics data, obtained through processing by the GPU 119, to the outside of the SoC 110 through the external memory controller 115. The transaction unit 117 may monitor data transactions of the function blocks, and the PMIC 118 may control power supplied to the function blocks, based on control by the transaction unit 117. The display controller 113 may control a display (or a display device) outside the SoC 110, and thus, may transmit data, generated in the SoC 110, to the display. The memory 114 may include a non-volatile memory such as EEPROM or flash memory, or may include a volatile memory such as DRAM or SRAM.

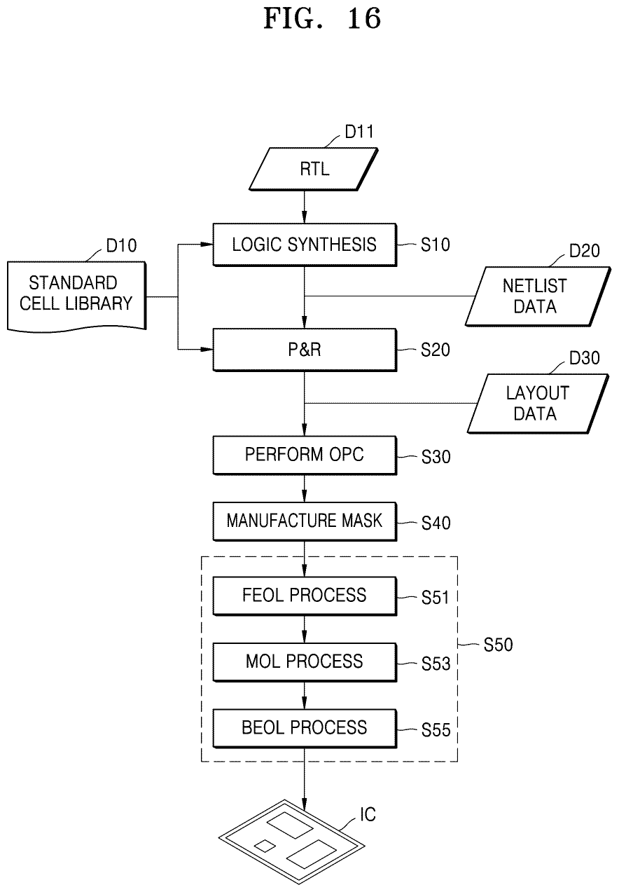

FIG. 16 is a flowchart illustrating a method of manufacturing an integrated circuit, according to one or more embodiments.

Referring to FIG. 16, a standard cell library D10 may include information (for example, function information, characteristic information, and layout information) about standard cells. The standard cell library D10 may include data which defines a layout of a standard cell. For example, data may include data which defines a structure of each of the standard cells C1, C2, and C3 described above with reference to FIGS. 5, 8, and 9, and moreover, may include data which defines a structure of each of standard cells including a bar-type active via or a bar-type gate contact.

Operations S10 and S20 may be an operation of designing an integrated circuit IC and may generate layout data D30 from register transfer level (RTL) data D11. In operation S10, a logic synthesis operation of generating netlist data D20 from the RTL data D11 may be performed. For example, a semiconductor design tool (for example, a logic synthesis module) may perform logic synthesis with reference to the standard cell library D10 from the RTL data D11 written in hardware description language (HDL) such as Verilog and VHSIC hardware description language (VHDL), and thus, may generate the netlist data D20 including bitstream or netlist. The standard cell library D10 may perform the same function and may include data which defines a structure of each of standard cells having different layouts, and moreover, standard cells may be included in the integrated circuit IC with reference to the standard cell library D10.

In operation S20, a place and routing (P&R) operation of generating layout data D30 from the netlist data D20 may be performed. The layout data D30 may have, for example, a format such as GDSII, and moreover, may include geometric information about interconnections and standard cells.

For example, the semiconductor design tool (for example, a P&R module) may place a plurality of standard cells with reference to the standard cell library D10 from the netlist data D20. The semiconductor design tool may select one layout from among layouts of a standard cell defined by a netlist D103 and may place the selected layout of the standard cell.

In operation S20, a routing operation of generating interconnections may be further performed. The interconnection may electrically connect an output pin and an input pin of the standard cell to another standard cell, and for example, the interconnection may include a plurality of vias and a conductive routing wiring formed in at least one wiring layer. In one or more embodiments, a routing wiring and a via which are formed when connecting each of the standard cells C1, C2, and C3, described above with reference to FIGS. 5, 8, and 9, to another standard cell may be generated.

An integrated circuit designing operation including operations S10 and S20 may be performed by a computing system for designing an integrated circuit including a processor and a memory. For example, a synthesis program for performing operation S10 and a P&R program for performing operation S20 may be loaded into a memory of the computing system, and a processor may execute the programs, whereby an operation of designing an integrated circuit may be performed.

In operation S30, optical proximity correction (OPC) may be performed. The OPC may correct a distortion phenomenon such as refraction caused by a characteristic of light in photolithography included in a semiconductor process of manufacturing the integrated circuit IC, and thus, may be referred to as an operation of forming a pattern having a desired shape, whereby a pattern of a mask may be determined by applying the OPC to the layout data D30. In one or more embodiments, a layout of the integrated circuit IC may be restrictively modified in operation S30, and an operation of restrictively modifying the integrated circuit IC in operation S30 may be post-processing for optimizing a structure of the integrated circuit IC and may be referred to as design polishing.

In operation S40, an operation of manufacturing a mask may be performed. For example, as the OPC is applied to the layout data D30, patterns of the mask may be defined for forming patterns formed in a plurality of layers, and at least one mask (or photomask) for forming patterns of each of the plurality of layers may be manufactured.

In operation S50, an operation of manufacturing the integrated circuit IC may be performed. For example, the plurality of layers may be patterned by using at least one mask which is manufactured in operation S40, and thus, the integrated circuit IC may be manufactured. Operation S50 may include operations S51, S53, and S55.

In operation S51, a front-end-of-line (FEOL) process may be performed. FEOL may denote a process of forming individual elements (for example, a transistor, a capacitor, and a resistor) in a substrate in a manufacturing process of the integrated circuit IC. For example, the FEOL process may include an operation of planarizing and cleaning a wafer, an operation of forming a trench, an operation of forming a well, an operation of forming a gate line, and an operation of forming a source and drain region.

In operation S53, a middle-of-line (MOL) process may be performed. MOL may denote a process of forming a connection member for connecting the individual elements, generated through the FEOL process, with each other in the standard cell. For example, the MOL process may include an operation of forming an active contact in an active region, an operation of forming a gate contact on the gate line, and an operation of forming an active via on the active contact, and particularly, may include an operation of forming the bar-type gate contact CBB or CBB′ or the bar-type active via VAB, VAB1, VAB2, VAB′, or VAB″ described above with reference to FIGS. 1 to 14B. A layer where elements formed by the MOL process is disposed may be defined as an MOL layer.

In operation S55, a back-end-of-line (BEOL) process may be performed. BEOL may denote a process of connecting, with each other, the individual elements (for example, the transistor, the capacitor, and the resistor) in the manufacturing process of the integrated circuit IC. For example, the BEOL process may include an operation of performing silicidation on the source and drain region, an operation of adding a dielectric, an operation of performing planarization, an operation of forming a hole, an operation of forming a plurality of wiring layers, an operation of forming a plurality of vias between the plurality of wiring layers, and an operation of forming a passivation layer. Subsequently, the integrated circuit IC may be packaged in a semiconductor package and may be used as a component for various applications.

Hereinabove, exemplary embodiments have been described in the drawings and the specification. Embodiments have been described by using the terms described herein, but this has been merely used for describing the disclosure and has not been used for limiting a meaning or limiting the scope of the disclosure defined in the following claims. Therefore, it may be understood by those of ordinary skill in the art that various modifications and other equivalent embodiments may be implemented from the disclosure. Accordingly, the spirit and scope of the disclosure may be defined based on the spirit and scope of the following claims.

In the above embodiments, the active via connecting one active contact to at least two patterns or connecting at least two active contacts to one pattern is termed as a bar-type active via. Similarly, the gate contact connecting a gate line to at least two patterns or connecting at least two gate lines to one pattern is termed as a bar-type gate contact in the above embodiments. However, the shape or form of the active via and the gate contact may not be limited to a bar, and instead, may have a different shape or form, for example, a horizontally-extending form, for the same connection purposes, according to one or more embodiments. Further, to contact the at least two patterns, the at least two active contacts or the at least two gate lines, the bar-type active via or the bar-type gate contact may overlap the at least two patterns, the at least two active contacts or the at least two gate lines in the vertical direction.

While the disclosure has been particularly shown and described with reference to embodiments thereof, it will be understood that various changes in form and details may be made therein without departing from the spirit and scope of the following claims.

What is claimed is:

1. An integrated circuit comprising:
a first wiring layer comprising a plurality of patterns each extending in a first horizontal direction;
an active contact; and
an active via connecting the active contact and at least two patterns among the plurality of patterns and extending along the active contact.

2. The integrated circuit of claim 1, wherein:
the integrated circuit comprises a first standard cell and a second standard cell,
a plurality of tracks extending in the first horizontal direction and arranged in a second horizontal direction, intersecting the first horizontal direction, are in the first wiring layer,
the active via contacts the at least two patterns in at least two tracks, respectively, among the plurality of tracks, and
one of the at least two patterns is connected to an output pin of the first standard cell, and the other of the at least two patterns is connected to an input pin of the second standard cell.

3. The integrated circuit of claim 1, further comprising a source/drain region connected to a lower portion of the active via.

4. The integrated circuit of claim 1, wherein the first wiring layer comprises:
a first power rail configured to provide a first supply voltage; and
a second power rail configured to provide a second supply voltage, and
wherein the active via is connected to one of the first power rail and the second power rail.

5. The integrated circuit of claim 1, further comprising:
a gate line extending in the first horizontal direction; and
a nanosheet-shaped active region surrounded by the gate line.

6. The integrated circuit of claim 5, further comprising a gate contact connecting the first wiring layer and the gate line.

7. The integrated circuit of claim 1, further comprising:
a second wiring layer disposed on the first wiring layer and comprising at least one pattern extending in a second horizontal direction intersecting the first horizontal direction; and
a via layer connecting the first wiring layer and the second wiring layer.

8. The integrated circuit of claim 1, wherein the integrated circuit comprises:
a memory cell block; and
a peripheral circuit configured to input or output data to or from the memory cell block, and
wherein the integrated circuit is static random access memory (SRAM).

9. The integrated circuit of claim 8, wherein the active via is formed in the peripheral circuit.

10. An integrated circuit comprising:
a wiring layer comprising a plurality of patterns each extending in a first horizontal direction;
a first gate line and a second gate line each extending in a second horizontal direction intersecting the first horizontal direction; and
a first gate contact connecting the first gate line and at least two patterns among the plurality of patterns or connecting the first gate line, the second gate line and a pattern among the plurality of patterns.

11. The integrated circuit of claim 10, wherein the first gate contact is a bar-type gate contact extending along the first gate line to overlap the at least two patterns in a vertical direction.

12. The integrated circuit of claim 11, further comprising:
a second gate contact connecting the second gate line and the at least two patterns among the plurality of patterns.

13. The integrated circuit of claim 10, further comprising:
wherein the first gate contact is a bar-type gate contact extending in the first horizontal direction and connects the first gate line and the second gate line.

14. The integrated circuit of claim 10, further comprising:
an active contact extending in the second horizontal direction; and
an active via extending along the contact in the second horizontal direction and connecting the active contact and the at least two patterns or another at least two patterns in the wiring layer.

15. The integrated circuit of claim 10, wherein the integrated circuit comprises:
a memory cell block; and
a peripheral circuit configured to input or output data to or from the memory cell block,
wherein the integrated circuit is static random access memory (SRAM), and
16. An integrated circuit comprising:
a wiring layer comprising a plurality of patterns each extending in a first horizontal direction;
an active contact; and
an active via connecting the active contact and the wiring layer,
wherein the active via overlaps a first pattern and a second among the plurality of patterns in a vertical direction, and extends along the active contact.

17. The integrated circuit of claim 16, further comprising:
a gate line extending in a second horizontal direction intersecting the first horizontal direction; and
a gate contact connecting the gate line and the wiring layer,
wherein the gate contact overlaps a third pattern and a fourth pattern among the plurality of patterns in the wiring layer in the vertical direction.

18. The integrated circuit of claim 17, wherein the gate contact is disposed on the gate line and extends along the gate line.

19. The integrated circuit of claim 16, wherein
a first track and a second track each extending in the first horizontal direction and arranged apart from each other in a second horizontal direction in the wiring layer, the first track and the second track being configured to transfer a signal, and
the active via is connects the first pattern of the first track and the second pattern of the second track.

20. The integrated circuit of claim 19, wherein:
the wiring layer comprises a power rail configured to provide a supply voltage, and
one of the first pattern and the second pattern is the power rail.
